(19) United States
(12) Patent Application Publication
(10) Pub. No.: US 2022/0373723 A1
(43) Pub. Date: Nov. 24, 2022

(54) OPTICAL ELEMENT HAVING A PROTECTIVE COATING, METHOD FOR THE PRODUCTION THEREOF AND OPTICAL ARRANGEMENT

(71) Applicant: Carl Zeiss SMT GmbH, Oberkochen (DE)

(72) Inventors: Konstantin FORCHT, Aalen (DE); Alexei POUKHOVOI, Aalen (DE)

(21) Appl. No.: 17/836,367

(22) Filed: Jun. 9, 2022

Related U.S. Application Data
(63) Continuation of application No. PCT/EP2020/082272, filed on Nov. 16, 2020.

(30) Foreign Application Priority Data
Dec. 9, 2019 (DE) 10 2019 219 177.0

(51) Int. Cl. G02B 5/08; C23C 16/455; C23C 16/56; G03F 7/20

(52) U.S. Cl. CPC G02B 5/0833; G02B 5/0891; C23C 16/45525; C23C 16/56; G03F 7/7085

(57) ABSTRACT

An optical element includes: a substrate, a reflective coating, applied to the substrate, for reflecting radiation in a first wavelength range (Δλ₁) between 100 nm and 700 nm, preferably between 100 nm and 300 nm, more preferably between 100 nm and 200 nm, and a protective coating applied to the reflective coating. The substrate is formed from a material which is transparent to the radiation in the first wavelength range (Δλ₁). The reflective coating is applied to a rear face of the substrate and is structured to reflect radiation that passes through the substrate to the reflective coating. Also disclosed are an optical arrangement with at least one such optical element and a method of producing such an optical element.

### CROSS-REFERENCE TO RELATED APPLICATION

This is a Continuation of International Application PCT/EP2020/082272, which has an international filing date of Nov. 16, 2020, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2019 219 177.0 filed on Dec. 9, 2019.

### FIELD

The techniques disclosed herein relate to an optical element comprising: a substrate, a reflective coating, applied to the substrate, for reflection of radiation in a first wavelength range between 100 nm and 700 nm, preferably between 100 nm and 300 mm, more preferably between 100 nm and 200 nm (the Vacuum Ultraviolet (VUV) wavelength range according to DIN 5031 Part 7), and a protective coating applied to the reflective coating, in particular for protection of the reflective coating from oxidation. The disclosed techniques also relate to an optical arrangement with at least one such optical element and to a method of producing such an optical element.

### BACKGROUND

Optical arrangements or systems suitable for the VUV wavelength range, for example from a wavelength of 100 nm, consist predominantly of reflective optical elements (mirrors). Optical systems using reflective optical elements can be manufactured that are not limited in terms of their imaging quality by longitudinal chromatic aberrations. Longitudinal chromatic aberrations are caused by the dispersion of any known optics material, for example magnesium fluoride, when refractive optics are used in the beam path. The mirrors of such optical systems that are used, for example, for the inspection of wafers (cf., for example, US 2016/0258878 A1) have to be provided with a reflective coating suitable for the respective useful wavelength range.

In the context of this application, a reflective coating for reflection of radiation in a first wavelength range is understood to mean a coating having a reflectance of more than 60% for radiation in at least one subrange of the first wavelength range or over the entire first wavelength range. The first wavelength range may be composed of one or more noncontiguous subranges. For example, in addition to the useful radiation, it is also possible to inject radiation in a wavelength range around about 700 nm into the beam path, which is to be reflected at the reflective coating. The additional radiation may be utilized for, for example, additional measurement devices, such as an autofocus device. It is thus possible but not necessary for the reflective coating to have a reflectance of more than 60% over the entire first wavelength range.

Reflective coatings (i.e., coatings with reflectance >60%) for the VUV wavelength range of 100 nm or higher usually include an aluminium layer protected by one or more fluoride layers (cf., for example, US 2017/0031067 A1 or the article: S. Wilbrandt, O. Stenzel, H. Nakamura, D. Wulff-Molder, A. Duparré, and N. Kaiser, “Protected and enhanced aluminium mirrors for the VUV,” Appl. Opt. 53, A125-A130 (2014)). Such constructions may be particularly beneficial when a high reflectivity over a wide wavelength range is intended, such as wavelength ranges between about 100 nm and about 1000 nm.

Other possible constructions for reflective coatings, such as coatings designed to reflect a VUV wavelength range between 100 nm and 300 nm or between 100 nm and 200 mm, may utilize a multilayer coating composed of dielectric materials without any metal layer. In such cases, the wavelength range in which the radiation is reflected is much smaller than in the case of an aluminium layer (cf., for example, the article: Luis Rodriguez-de Marcos, Juan I. Larruquert, José A. Méndez, and José A. Aznárez “Multilayers and optical constants of various fluorides in the far UV”, Proc. SPIE 9627, Optical Systems Design 2015: Advances in Optical Thin Films V, 96270B (Sep. 23, 2015)). Other constructions for reflective coatings may utilize a metal layer, in particular an aluminium layer, to which a dielectric multilayer coating is applied, in order to specifically increase the reflectance of the optical element for particular wavelength ranges, as described in, for example, DE 10 2015 218 763 A1.

US 2017/0031067 A1 describes a mirror for the vacuum ultraviolet (VUV) wavelength range, having a substrate to which a first layer is applied, which layer may be of aluminium. Two further layers of fluorides are applied to the layer of aluminium.

DE 10 2018 211 498 A1 describes an optical element having a reflective face having a protective layer of fluorides. The optical element may be designed for the VUV wavelength range. The reflective face may be designed as a coating of a substrate and have a metal layer, which is in particular a layer of aluminium or an aluminium alloy.

The publication by Minghong Yang, Alexandre Gatto, and Norbert Kaiser “Highly reflecting aluminium-protected optical coatings for the vacuum-ultraviolet spectral range”, Appl. Opt. 45, 178-183 (2006), describes reflective layers for the VUV wavelength range that have a metal layer, in particular a layer of aluminium, and protective layers of fluorides and oxides. It has been found that the reflective coating of the mirror described in the publication, in spite of the protective layer, is not stable under irradiation with high powers of more than 1 W/cm² in the wavelength range of 100 nm or higher under customary ambient conditions over several months. Customary ambient conditions are inert gases (e.g., N₂, Ar) with less than 5 ppm of oxygen and 5 ppm of water. The degradation of the reflective coating leads to a significant deterioration in the reflection of the optical element and to an increase in scattered light. It will be apparent that a higher oxygen or water content in the environment of the reflective optical element will further shorten the lifetime of the reflective coating.

In an analysis of the degradation phenomena, it has been found that aluminium, in particular, may become oxidized after prolonged irradiation. Moreover, it is also possible for fluorides in the protective coating to undergo chemical alteration. Attempts to improve the protective coating in order to reduce the diffusion of oxygen and water through the protective coating to a sufficient degree have been found to be problematic, or it was necessary to choose a sufficiently high thickness of the protective coating that the reflectance of the reflective coating was distinctly reduced.

### SUMMARY

It is an object of example embodiments of the disclosed techniques to provide an optical element, an optical arrangement having such an optical element, and a method of producing an optical element, which enable effective protection of the reflective coating from degradation.

This object may be achieved by an optical element in which the substrate is formed from a material which is transparent to the radiation in the first wavelength range, and in which the reflective coating is applied to a rear face of the substrate and is designed to reflect radiation that passes through the substrate to the reflective coating. The radiation that passes from the front face through the substrate thus first hits not the protective coating, but rather the reflective coating.

It is proposed in accordance with the disclosed techniques that the protective effect of the protective coating is improved in that the reflective optical element is designed as a rear-surface mirror (also known as a Mangin mirror). In the case of such a mirror, the protective coating is applied to a side of the reflective coating remote from the substrate, such that it is unnecessary for the protective coating to be transparent to the radiation in the first wavelength range.

In one embodiment, the protective coating has a thickness of at least 50 nm, preferably of at least 90 nm, and in particular of at least 120 nm. As described above, it is unnecessary for the radiation to be able to pass through the protective coating of the optical element. Accordingly, the protective coating, in order to increase the protective effect, may have a much greater thickness than is the case in the protective coating described in Minghong Yang, Alexandre Gatto, and Norbert Kaiser “Highly reflecting aluminum-protected optical coatings for the vacuum-ultraviolet spectral range”, Appl. Opt. 45, 178-183 (2006).

In a further embodiment, the protective coating has at least one layer of an oxidic material which is preferably selected from the group that includes: Al₂O₃, SiO₂, MgO, BeO, La₂O₃ and mixtures or combinations thereof. Oxidic materials have been found to be advantageous for the protective coating, as these materials can be applied or deposited with a particularly high density. For the deposition of particularly dense layers of oxidic materials inter alia, atomic layer deposition (ALD) has been found to be advantageous; cf., for example, the article “Mirror Coatings with Atomic Layer Deposition: Initial Results” by F. Geer et al., Proc. SPIE 8442, Space Telescopes and Instrumentation 2012: Optical, Infrared and Millimeter Wave, 84421J, the article “Enabling High Performance Mirrors for Astronomy with ALD”, ECS Transactions, 50 (13), 141-148 (2012), or the article “Study of a novel ALD process for depositing MgF₂ thin films”, Tero Plivi et al., J. Mater. Chem. 2007, 17, 5077-5083. In particular, aluminium oxide (Al₂O₃) applied by atomic layer deposition has been found to be beneficial as a material for the protective coatings of the disclosed techniques. In the context of this application, a protective coating is understood to mean a coating that may have one layer or multiple layers.

In a further embodiment, the protective coating has at least one layer of a material non-transparent to the first wavelength range. As described above, it is not necessary for the materials of the protective coating to have good transmittance for radiation in the first wavelength range, for example in the VUV wavelength range. The selection of materials which can be used for the protective coating described here is therefore much greater than in the case of a protective coating applied to the front face of a reflective optical element.

Suitable essentially non-transparent materials include, for example: Y₂O₃, Yb₂O₃, HfO₂, Sc₂O₃, Nb₂O₅, Ta₂O₅, TiO₂, SnO₂, ZrO₂, ZnO, Al, Cr, Ta, Hf, Ti, Sc, Nb, Zr and mixtures or combinations thereof. These mixtures or combinations may also include the abovementioned oxides Al₂O₃, SiO₂, MgO, BeO and La₂O₃.

In a further embodiment, the reflective coating includes of at least one layer of a metallic material, in particular of aluminium or an aluminium alloy. As described above, the reflective coating may be formed from one layer or optionally from multiple layers of metallic materials, specifically from aluminium or an aluminium alloy, in order to reflect radiation within a large wavelength range, for example between about 100 nm and about 1000 nm. In the case of a purely metallic reflective coating, applying a protective layer to the side remote from the substrate may not be necessary, since the radiation typically does not reach the side or surface of the reflective coating remote from the substrate. In this case, i.e., if the surface of the metallic material is exposed to virtually no radiation, the degradation of the metallic material is generally low.

In another example of the disclosed techniques, the reflective coating includes a multilayer coating having a plurality of alternating layers composed of materials, in particular of dielectric materials, having different refractive indices. Such reflective coatings may consist of just the multilayer coating, or they may include additional layers or materials. A multilayer coating typically serves to generate high reflectivity in a predefined, generally comparatively small wavelength range by constructive interference, which is generated on reflection of the radiation at the interfaces between the layers. For this purpose, the multilayer system typically has alternately applied layers of a material with a higher real part of the refractive index in the first wavelength range and of a material having a lower real part of the refractive index in the first wavelength range. The thicknesses of the alternating layers are fixed depending on the wavelength range for which the reflective coating is to have maximum reflectivity. In general, in the case of such a multilayer coating, the thickness of the layers having a lower real part of the refractive index and the thickness of the layers having a higher real part of the refractive index is constant. In general, a reflective multilayer coating does not have more than about fifty pairs of alternating layers.

In other examples of the disclosed techniques, the multilayer coating has at least one layer of a fluoridic material which is preferably selected from the group that includes: AlF₃, LiF, BaF₂, NaF, MgF₂, CaF₂, LaF₃, GdF₃, HoF₃, YbF₃, YF₃, LuF₃, ErF₃, Na₃AlF₆, Na₅Al₃F₁₄, ZrF₄, HfF₄ and combinations thereof. The reflective coating may have two different materials from the group described here. The use of fluoridic materials has been found to be beneficial in order to generate high reflectivity in a wavelength range between 100 nm and 700 nm, preferably between 100 nm and 300 nm, and more preferably between 100 nm and 200 nm.

In one specific example of the disclosed techniques, at least one layer of a metallic material is applied to the multilayer coating, preferably formed from aluminium or an aluminium alloy. In this example, the reflective coating is a dielectrically enhanced metallic coating. According to this example, the protective coating is applied to the at least one layer of the metallic material.

In another specific example, the protective coating takes the form of a multilayer coating having a plurality of alternating layers of dielectric materials having different refractive indices. If the protective coating itself takes the form of a multilayer coating, this may contribute to an increase in the reflectivity of the optical element in addition to the reflective coating. The use of multilayer protective coatings may be beneficial to increasing reflectance in a subrange of the first wavelength range in which the reflective coating itself may not provide sufficiently high reflectivity, for example in the case of wavelengths of more than 250 nm. In such examples, the reflective coating is generally formed from fluoridic materials, whereas the protective coating is formed from oxidic materials.

In the case of known optical systems with Mangin mirrors, for example a lens as described in DE 10 2017 202 802 A1, the radiation path in the substrate is long because the respective substrate should have a typical thickness/diameter ratio of less than about 1:15 in order to achieve the necessary precision of the surface form and to achieve mechanical stability. The comparatively high thickness of the substrate leads to radiation losses through absorption within the substrate.

In a further example of the disclosed techniques, the optical element may include a further substrate on which a surface is formed, which is bonded to a surface of the protective coating by a direct bond, in particular by direct bonding. The surface bonded to the surface of the protective coating is preferably formed atop a coating applied to the further substrate. A direct bond in the context of this disclosure is understood to mean a bond between the two surfaces without any bonding agent, in particular without any interlayer present between the surfaces, for example in the form of an adhesive. The further substrate, which may be a ceramic material, serves as carrier substrate and increases the mechanical stability of the optical element.

Mirror optics having a sheet of ceramic on which a thin sheet of glass is applied with the aid of a connecting layer is described in DE 10 2005 052 240 A1, is the entire contents of which are incorporated into this application by reference. DE 10 2005 052 240 A1 states that the bond between the sheet of ceramic and the thin sheet of glass can be made with the aid of a specialty adhesive, a fusion, a galvanic bond or some other conceivable form. In the optical element described here, the bond to the further substrate is made by a direct bond because, when a bonding agent is used, such as an adhesive, there is no prolonged mechanical stability, and so the shape of the surface is altered. This problem may be avoided in the case of a direct bond.

For direct bonding, and for low-temperature direct bonding specifically, it has been found to be beneficial for the protective coating, or at least at the surface thereof, to be formed from an oxidic material that is the same oxidic material that forms the surface of the further substrate. For direct bonding, it is generally advantageous when the two surfaces that are bonded to one another are constructed from one and the same material. If the material of the further substrate does not correspond to the material of the protective coating, it is possible to apply a layer or coating of the material of the protective coating to the further substrate. Alternatively, it is optionally possible to apply an adhesion promoter layer or a layer of the same material as the surface of the further substrate to the protective coating.

Direct bonding of two surfaces is possible, particularly in the case of oxide materials, such as SiO₂, cf., for example, the article “Novel hydrophilic SiO₂ wafer bonding using combined surface-activated bonding technique” by Ran He et al., Jpn. J. Appl. Phys. 54, 030218 (2015). Other types of direct bonding than the direct bonding described therein may also be used for bonding to the further substrate, provided that the types of direct bonding have prolonged stability.

In other examples of the disclosed techniques, the substrate may have a thickness of less than 5 mm, and preferably of less than 1 mm. The substrate may have a particularly low thickness, particularly in the case that it is secured to the further substrate as described above. The further substrate in this case serves as carrier substrate, and generally has a much greater thickness than the substrate. The substrate can be removed by mechanical processing, for example by lapping and polishing, down to the above-specified thickness at which the absorption in the substrate no longer leads to noticeable radiation losses. Alternatively, to mechanical processing or the removal of the substrate material after bonding to the carrier substrate, it is possible to use a substrate having the above-specified thickness that has already been lapped or polished.

In another example of the disclosed techniques, the substrate, the further substrate, the protective coating, the reflective coating and preferably the coating of the further substrate are transparent to a second wavelength range different than the first wavelength range. The second wavelength range preferably has greater wavelengths than the first wavelength range, and the second wavelength range preferably between 200 nm and 2000 nm, and in particular between 200 nm and 1000 nm. Additionally, the radiation in the second wavelength range may not reflected by the reflective coating in specific examples.

The radiation in the second wavelength range may be radiation which is directed onto the optical element to provide additional functions, such as heating or temperature control of the substrate. The radiation in the second wavelength range may be light unsuitable for the optical application of the radiation in the first wavelength range and may be separated from the radiation in the first wavelength range by the device described here or by the optical element.

An optical element according to such examples enables control of temperature since radiation in the second wavelength range, for example radiation in the IR wavelength range above 1000 nm, can be injected from the rear side of the further substrate and passes through the protective coating and the reflective coating into the substrate. The substrate may, in particular, have zero or only low transmittance for the second wavelength range, such that the radiation in the second wavelength range is absorbed by the substrate, and the desired temperature control is enabled or simplified. For monitoring of the temperature of the optical element or substrate, a temperature sensor may be mounted on or close to the optical element.

An optical element in which the reflective coating, the protective layer and, if present, the further substrate are transparent to the radiation in the second wavelength range is also beneficial when the optical element is to be used as a beam splitter. In such examples, the optical element divides the radiation incident on the front face of the substrate into two wavelength ranges, with radiation in the first wavelength range being reflected at the reflective coating and radiation in the second wavelength range being transmitted by the reflective coating, the protective layer and, if present, the further substrate.

In principle, it is also possible that the substrate, the further substrate, the protective coating, the reflective coating and/or any coating present on the further substrate are non-transparent or opaque to further radiation in the second wavelength range.

In a further example of the disclosed techniques, a coefficient of thermal expansion of the substrate and a coefficient of thermal expansion of the further substrate bonded to the substrate differ by not more than 5*10⁻⁶K⁻¹. The linear coefficients of thermal expansion for the substrate and the further substrate may both be linear coefficients of thermal expansion. When the coefficients of thermal expansion for the substrate and further substrate differ by not more than 5*10⁻⁶K⁻¹, the deformation of the substrates due to different expansion of the substrate materials is reduced. The criterion mentioned is fulfilled may be fulfilled when the two substrates are manufactured from the same material. However, material combinations are also possible, for example MgF₂ (for the substrate) and MgO (for the further substrate).

In a further example of the disclosed techniques, the substrate and, if present, the further substrate are formed from a fluoridic material preferably selected from the group that includes: CaF₂, MgF₂, LiF, LaF₃, BaF₂ and SrF₂. These enumerated materials are transparent to wavelength range of more than 100 nm (e.g., the above described first wavelength range). As described above, it is not necessary for the material of the further substrate to be transparent for the radiation in the first wavelength range.

A further aspect of the disclosed techniques relate to an optical arrangement, in particular a wafer inspection device, comprising: a radiation source for generating radiation in a first wavelength range between 100 and 450 nm, preferably between 100 nm and 300 mm, and more preferably between 100 nm and 200 nm, and at least one optical element as described above. The optical arrangement may be designed to direct the radiation from the radiation source onto a front face of the substrate. In such an arrangement, the optical element is used as a rear-surface mirror, in which the radiation in the first wavelength range which is incident on the front face of the substrate and is reflected at the reflective coating applied to the rear face of the substrate.

The optical arrangement may be a wafer inspection system; cf., for example, the article “Extending Optical Inspection to the VUV”, K. Wells, Int. Conf. of Frontiers of Characterization and Metrology for Nanoelectronics, FCMN, 2017, pp. 92-101. The optical arrangement may also be is an inspection device for inspection of masks or another kind of optical arrangement, for example a lithography system, such as a VUV lithography system, or the like.

In one example of the disclosed techniques, the radiation source and/or a further radiation source is designed to generate further radiation at least in a second wavelength range different than the first wavelength range. The second wavelength range preferably has greater wavelengths than the wavelengths of the first wavelength range. The second wavelength range may include wavelengths preferably between 200 nm and 2000 nm, and in particular between 200 nm and 1000 nm. In such examples, the optical arrangement may be designed to direct the further radiation in the second wavelength range onto the front face or onto the rear face of the substrate.

Such examples may be particularly beneficial for optical element in which the substrate, the reflective coating and the protective coating are not transparent in the second wavelength range (i.e., the wavelength range that is different than the first wavelength range). If, in this example, the further radiation is emitted or outcoupled, for example in the form of heating radiation in the IR wavelength range—optionally through the further substrate—onto the rear face of the substrate, the heating radiation in the second wavelength range can result in control of the temperature of the substrate or of the optical element. If the radiation in the second wavelength range is emitted from the front face, and the reflective coating, the protective coating and the substrate are transparent to the radiation in the second wavelength range, the optical element may serve as beam splitter. In this example, the radiation generated by the radiation source or optionally by multiple radiation sources may be divided into two wavelength ranges at the optical element, one of which is reflected as useful radiation and the other of which is trapped, for example in a beam trap or the like.

The disclosed techniques also relate to a method of producing a reflective optical element, in particular of the type as described above, comprising: applying a reflective coating to the rear face of a substrate, wherein the reflective coating is designed to reflect radiation in a first wavelength range between 100 nm and 700 nm, preferably between 100 nm and 300 nm, and more preferably between 100 nm and 200 nm. In such examples, the reflective coating applied to the rear face of the substrate may be configured to transmit further radiation in a second wavelength range different than the first, which passes through the substrate to the reflective coating. In such examples, the substrate may be formed from a material transparent to the radiation in the first wavelength range and preferably transparent to the further radiation in the second wavelength range. The method may also include applying a protective coating to the reflective coating which preferably has a thickness of at least 50 nm, preferably of at least 90 nm, and in particular of at least 120 nm.

In particular, if the reflective coating includes a multilayer coating or consists of a multilayer coating, a reflective coating that is applied to the rear face of the optical element and serves to reflect radiation that passes through the substrate to the reflective coating differs from a reflective coating that is applied to the front face of the substrate and serves to reflect radiation that hits the front face of the substrate or the reflective coating formed there.

The design of such a reflective coating depends on the optical medium formed at the interface between the reflective coating and the environment. The reflective coating applied to the rear face, in the case of this optical medium, is the material of the substrate (refractive index n greater than 1.0), whereas the reflective coating applied to the front face, in the case of the surrounding medium, is air or a vacuum environment (refractive index n=1.0).

In one specific example, the method includes: directly bonding a surface of the protective coating to a surface formed on a further substrate, preferably on a coating applied to the substrate. As described above, the further substrate may be a carrier substrate that increases the mechanical stability of the optical element and enables a reduction in the thickness of the substrate.

In a further specific example of the disclosed techniques, the protective coating, at least at the surface, is preferably formed from an oxidic material, and the surface of the further substrate includes the same, preferably oxidic, material formed on the surface of the protective coating. The use of two identical materials, for example of two oxides, for establishment of a bond that does not need any bonding agent has been found to be beneficial. The direct bond can be established, for example, with the surface-activated direct bonding described above. However, it is not necessary for the two surfaces at which the direct bond is formed to be formed from the same material. In particular when the further substrate itself is an oxidic material, this may optionally be bonded directly, i.e., without the application of a layer of an oxidic material, to the surface of the protective coating.

In a further example, the method may include: removing material from the front face of the substrate in order to reduce the thickness of the substrate. The removal can be effected, for example, by lapping and/or polishing. Material is typically removed from the substrate until a thickness is reached that no longer leads to noticeable losses of absorption of the radiation passing through the substrate. Such removal may be particularly beneficial when the substrate is applied to the further substrate described above (e.g., a carrier substrate).

In some specific examples, the protective coating is applied to the reflective coating by atomic layer deposition. The deposition of the protective coating, for example in the form of an oxide, onto the rear side of the substrate by atomic layer deposition has been found to be beneficial as this method enables the deposition of particularly dense layers. Instead of atomic layer deposition, it is also possible to apply the protective coating and the reflective coating using conventional deposition methods, for example through physical vapor deposition (PVD) or chemical vapor deposition (CVD).

Further features and advantages of the disclosed techniques will be apparent from the description of working examples that follows, with reference to the figures of the drawing, which show details essential to the working examples, and from the claims. The individual features can each be realized individually by themselves or as a plurality in any desired combination.

### BRIEF DESCRIPTION OF THE DRAWINGS

Working examples are shown in the schematic drawing and are elucidated in the description that follows. The figures show:

FIG. 1A illustrates a schematic diagram of a first optical element for reflection of radiation in the VUV wavelength range, which has a protective coating and a reflective coating on its rear side, according to an example embodiment,

FIG. 1B illustrates a schematic diagram of a second optical element for reflection of radiation in the VUV wavelength range, which has a protective coating and a reflective coating on its rear side, according to an example embodiment,

FIG. 1C illustrates a schematic diagram of a third optical element for reflection of radiation in the VUV wavelength range, which has a protective coating and a reflective coating on its rear side, according to an example embodiment,

FIG. 1D illustrates a schematic diagram of a fourth optical element for reflection of radiation in the VUV wavelength range, which has a protective coating and a reflective coating on its rear side, according to an example embodiment,

FIG. 2A is a first schematic diagram of two steps of the production of an optical element, in which the protective coating is bonded to a carrier substrate, according to an example embodiment,

FIG. 2B is a second schematic diagram of two steps of the production of an optical element, in which the protective coating is bonded to a carrier substrate, according to an example embodiment,

FIG. 3A is a first schematic diagram of the optical element of FIGS. 2A and 2B with a reflective coating transparent to radiation in a second wavelength range, according to an example embodiment,

FIG. 3B is a second schematic diagram of the optical element of FIGS. 2A and 2B with a reflective coating transparent to radiation in a second wavelength range, according to an example embodiment,

FIG. 4A is a graph of the reflectance of the optical element of FIGS. 1B, D and of FIG. 3A, B as a function of the wavelength, according to an example embodiment,

FIG. 4B is a graph of the transmittance of the optical element of FIGS. 1B, D and of FIGS. 3A, B as a function of the wavelength, according to an example embodiment, and

FIG. 5 is a diagram of a wafer inspection device with two optical elements for reflection of radiation in the VUV wavelength range.

### DETAILED DESCRIPTION

In the description of the drawings that follows, identical reference numbers are used for components that are the same or have the same function.

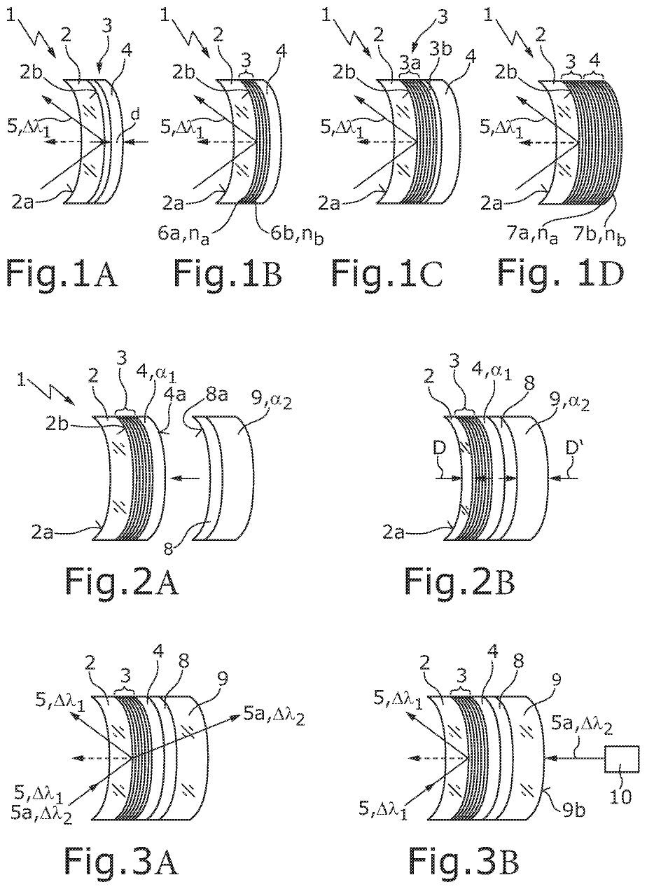

FIGS. 1A-D show an optical element 1 having a substrate 2 formed from a material transparent to radiation 5 within a broad wavelength range between 100 nm and 1000 nm. The material of substrate 2 may be, for example, CaF₂, MgF₂, LiF, LaF₃, BaF₂ or SrF₂. Applied to a rear face 2b of the substrate 2 is a reflective coating 3 which is designed to reflect radiation 5 in a first wavelength range Δλ₁ between 100 nm and 200 nm, which enters the substrate 2 at a front face 2a and passes through the substrate 2 to the reflective coating 3. The reflective coating 3 is typically what is called a highly reflective coating having a reflectance of more than 60% for the radiation 5 in the first wavelength range Δλ₁.

Applied to the reflective coating 3, on its face or surface remote from the substrate 2, is a protective coating 4 that protects the reflective coating 3 from oxidation, inter alia. Owing to the fact that the radiation 5 does not have to penetrate the protective coating 4 applied to the rear face 2b of the substrate 2, the protective coating 4 may in principle have a high thickness d. In order to achieve a sufficient protective effect for the reflective coating 3 that covers the protective coating 4, it has been found to be beneficial when the protective coating 4 has a thickness d of at least 50 nm, preferably of at least 90 nm, and in particular of at least 120 nm.

In the examples shown in FIGS. 1A-C, the protective coating 4 is composed of a layer 4 of an oxidic material, specifically of aluminium oxide (Al₂O₃). Alternatively, the protective coating may have one or more layers of another oxidic material, for example of SiO₂ or of MgO. The protective coating 4 may have at least one layer of a material which is non-transparent to the first wavelength range Δλ₁, i.e., to wavelengths between 100 nm and 200 nm. A material non-transparent to the first wavelength range Δλ₁ is understood to mean a material which, given a thickness of 100 nm, has a transmittance of less than 30% for radiation 5 in the first wavelength range Δλ₁. Accordingly, a material transparent to the first wavelength range Δλ₁ is understood to mean a material which, given a thickness of 100 nm, has a transmittance of more than 60% for radiation 5 in the first wavelength range Δλ₁.

In the optical element 1 shown in FIG. 1A, the reflective coating 3 is composed of a metallic material, more specifically of aluminium. The reflective coating 3 may alternatively be formed from another metallic material, for example from an alloy, e.g., an aluminium alloy.

Rather than a reflective coating 3 of a metallic material, the reflective coating 3 may be formed from dielectric materials. FIG. 1B shows such a reflective coating 3 that forms a multilayer coating having a plurality of pairs, for example about ten pairs, of alternating layers 6a and 6b of materials having different refractive indices nₐ and n_{b}, respectively. In order to generate high reflectivity in the first wavelength range Δλ₁ between 100 nm and 200 nm, it has been found to be beneficial when the materials of the reflective coating 3 are fluoridic materials, for example AlF₃, LiF, BaF₂, NaF, MgF₂, CaF₂, LaF₃, GdF₃, HoF₃, YbF₃, YF₃, LuF₃, ErF₃, Na₃AlF₆, Na₅Al₃F₁₄, ZrF₄, HfF₄ and combinations thereof.

FIG. 1C shows an optical element 1 in which the reflective coating 3 is a dielectrically enhanced metallic coating. The reflective coating 3 has a multilayer coating 3a to which a metallic layer 3b of, for example, aluminium is applied. The reflective coating 3 shown in FIG. 1C thus constitutes a combination of the reflective coating shown in FIG. 1A and that shown in FIG. 1B.

In the optical element 1 shown in FIG. 1D, the reflective coating 3 takes the form of a multilayer coating as in FIG. 1B. In addition, the protective coating 4 also takes the form of a multilayer coating and has a plurality of pairs of layers 7a and 7b, for example about ten pairs of layers 7a and 7b, with different refractive indices nₐ, and n_{b}, respectively. In this case, the protective layer 4 enables an increase in the reflectance R of the optical element 1 for the radiation in the first wavelength range Δλ₁. The table below gives one example each for the layer sequences and layer thicknesses of the layers of the reflective coating 3 and the protective coating 4 of the optical element of FIG. 1B and of FIG. 1D.

| | Reflective coating with | | Reflective coating with | |
|---|---|---|---|---|
| | single protective layer | | multilayer protective coating | |
| # | Material | Layer thickness | Material | Layer thickness |
| | First substrate | — | First substrate | — |
| | MgF₂ | | MgF₂ | |
| 1 | BaF₂ | 25.1 | BaF₂ | 25.1 |
| 2 | LiF | 28.0 | LiF | 28.0 |
| 3 | BaF₂ | 25.1 | BaF₂ | 25.1 |
| 4 | LiF | 28.0 | LiF | 28.0 |
| 5 | BaF₂ | 25.1 | BaF₂ | 25.1 |
| 6 | LiF | 28.0 | LiF | 28.0 |
| 7 | BaF₂ | 25.1 | BaF₂ | 25.1 |
| 8 | LiF | 28.0 | LiF | 28.0 |
| 9 | BaF₂ | 25.1 | BaF₂ | 25.1 |
| 10 | LiF | 28.0 | LiF | 28.0 |
| 11 | BaF₂ | 25.1 | BaF₂ | 25.1 |
| 12 | LiF | 28.0 | LiF | 28.0 |
| 13 | BaF₂ | 25.1 | BaF₂ | 25.1 |
| 14 | LiF | 28.0 | LiF | 28.0 |
| 15 | BaF₂ | 25.1 | BaF₂ | 25.1 |
| 16 | LiF | 28.0 | LiF | 28.0 |
| 17 | BaF₂ | 25.1 | BaF₂ | 25.1 |
| 18 | LiF | 28.0 | LiF | 28.0 |
| 19 | BaF₂ | 25.1 | BaF₂ | 25.1 |
| 20 | LiF | 28.0 | LiF | 28.0 |
| 21 | BaF₂ | 25.1 | BaF₂ | 25.1 |
| 22 | LiF | 28.0 | LiF | 28.0 |
| 23 | BaF₂ | 25.1 | BaF₂ | 25.1 |
| 24 | LiF | 28.0 | LiF | 28.0 |
| 25 | BaF₂ | 25.1 | BaF₂ | 25.1 |
| 26 | LiF | 28.0 | LiF | 28.0 |
| 27 | BaF₂ | 25.1 | BaF₂ | 25.1 |
| 28 | LiF | 29.9 | LiF | 29.9 |
| 29 | BaF₂ | 26.9 | BaF₂ | 26.9 |
| 30 | LiF | 29.9 | LiF | 29.9 |
| 31 | BaF₂ | 26.9 | BaF₂ | 26.9 |
| 32 | LiF | 29.9 | LiF | 29.9 |
| 33 | BaF₂ | 26.9 | BaF₂ | 26.9 |
| 34 | LiF | 29.9 | LiF | 29.9 |
| 35 | BaF₂ | 26.9 | BaF₂ | 26.9 |
| 36 | LiF | 29.9 | LiF | 29.9 |
| 37 | BaF₂ | 26.9 | BaF₂ | 26.9 |
| 38 | LiF | 29.9 | LiF | 29.9 |
| 39 | BaF₂ | 26.9 | BaF₂ | 26.9 |
| 40 | LiF | 29.9 | LiF | 29.9 |
| 41 | BaF₂ | 26.9 | BaF₂ | 26.9 |
| 42 | LiF | 29.9 | LiF | 29.9 |
| 43 | BaF₂ | 26.9 | BaF₂ | 26.9 |
| 44 | LiF | 29.9 | LiF | 29.9 |
| 45 | BaF₂ | 26.9 | BaF₂ | 26.9 |
| 46 | LiF | 29.9 | LiF | 29.9 |
| 47 | BaF₂ | 26.9 | BaF₂ | 26.9 |
| 48 | LiF | 29.9 | LiF | 29.9 |
| 49 | BaF₂ | 26.9 | BaF₂ | 26.9 |
| 50 | LiF | 29.9 | LiF | 29.9 |
| 51 | BaF₂ | 26.9 | BaF₂ | 26.9 |
| 52 | LiF | 29.9 | LiF | 29.9 |
| 53 | BaF₂ | 26.9 | BaF₂ | 26.9 |
| 54 | LiF | 29.9 | LiF | 29.9 |
| 55 | BaF₂ | 26.9 | BaF₂ | 26.9 |
| 56 | LiF | 29.9 | LiF | 29.9 |
| 57 | BaF₂ | 26.9 | BaF₂ | 26.9 |
| 58 | LiF | 29.9 | LiF | 29.9 |
| 59 | BaF₂ | 26.9 | BaF₂ | 26.9 |
| 60 | LiF | 31.2 | LiF | 31.2 |
| 61 | BaF₂ | 28.1 | BaF₂ | 28.1 |
| 62 | LiF | 31.2 | LiF | 31.2 |
| 63 | BaF₂ | 28.1 | BaF₂ | 28.1 |
| 64 | LiF | 31.2 | LiF | 31.2 |
| 65 | BaF₂ | 28.1 | BaF₂ | 28.1 |
| 66 | LiF | 31.2 | LiF | 31.2 |
| 67 | BaF₂ | 28.1 | BaF₂ | 28.1 |
| 68 | LiF | 31.2 | LiF | 31.2 |
| 69 | BaF₂ | 29.2 | BaF₂ | 29.2 |
| 70 | LiF | 32.5 | LiF | 32.5 |
| 71 | BaF₂ | 29.2 | BaF₂ | 29.2 |
| 72 | LiF | 32.5 | LiF | 32.5 |
| 73 | BaF₂ | 29.2 | BaF₂ | 29.2 |
| 74 | LiF | 32.5 | LiF | 32.5 |
| 75 | BaF₂ | 29.2 | BaF₂ | 29.2 |
| 76 | LiF | 32.5 | LiF | 32.5 |
| 77 | BaF₂ | 29.2 | BaF₂ | 29.2 |
| 78 | LiF | 32.5 | LiF | 32.5 |
| 79 | BaF₂ | 29.2 | BaF₂ | 29.2 |
| 80 | LiF | 32.5 | LiF | 32.5 |
| 81 | BaF₂ | 29.2 | BaF₂ | 29.2 |
| 82 | LiF | 32.5 | LiF | 32.5 |
| 83 | BaF₂ | 29.2 | BaF₂ | 29.2 |
| 84 | LiF | 32.5 | LiF | 32.5 |
| 85 | BaF₂ | 29.2 | BaF₂ | 29.2 |
| 86 | LiF | 32.5 | LiF | 32.5 |
| 87 | BaF₂ | 29.2 | BaF₂ | 29.2 |
| 88 | LiF | 32.5 | LiF | 32.5 |
| 89 | BaF₂ | 29.2 | BaF₂ | 29.2 |
| 90 | LiF | 32.5 | LiF | 32.5 |
| 91 | BaF₂ | 29.2 | BaF₂ | 29.2 |
| 92 | LiF | 32.5 | LiF | 32.5 |
| 93 | BaF₂ | 29.2 | BaF₂ | 29.2 |
| 94 | LiF | 32.5 | LiF | 32.5 |
| 95 | BaF₂ | 29.2 | BaF₂ | 29.2 |
| 96 | LiF | 32.5 | LiF | 32.5 |
| 97 | BaF₂ | 29.2 | BaF₂ | 29.2 |
| 98 | LiF | 32.5 | LiF | 32.5 |
| 99 | Al₂O₃ | 120 | Al₂O₃ | 26.5 |
| 100 | Environment or | — | SiO₂ | 32.2 |
| | further substrate | | | |
| 101 | | | Al₂O₃ | 26.5 |
| 102 | | | SiO₂ | 32.2 |
| 103 | | | Al₂O₃ | 26.5 |
| 104 | | | SiO₂ | 32.2 |
| 105 | | | Al₂O₃ | 26.5 |
| 106 | | | SiO₂ | 32.2 |
| 107 | | | Al₂O₃ | 26.5 |
| 108 | | | SiO₂ | 32.2 |
| 109 | | | Al₂O₃ | 26.5 |
| 110 | | | SiO₂ | 32.2 |
| 111 | | | Al₂O₃ | 26.5 |
| 112 | | | SiO₂ | 32.2 |
| 113 | | | Al₂O₃ | 26.5 |
| 114 | | | SiO₂ | 32.2 |
| 115 | | | Al₂O₃ | 26.5 |
| 116 | | | SiO₂ | 32.2 |
| 117 | | | Al₂O₃ | 26.5 |
| 118 | | | SiO₂ | 32.2 |
| 119 | | | Al₂O₃ | 26.5 |
| 120 | | | SiO₂ | 32.2 |
| 121 | | | Al₂O₃ | 26.5 |
| 122 | | | SiO₂ | 32.2 |
| 123 | | | Al₂O₃ | 26.5 |
| 124 | | | SiO₂ | 32.2 |
| 125 | | | Al₂O₃ | 26.5 |
| 126 | | | SiO₂ | 32.2 |
| 127 | | | Al₂O₃ | 26.5 |
| 100 | | | Environment or | — |
| | | | further substrate | |

In the example given in the table above, the reflective coating 3 has alternating layers 6a and 6b of LiF (nₐ=1.425 at 180 nm) and BaF₂ (n_{b}=1.583 at 180 nm), respectively, which have respective thicknesses of 32.5 nm to 28 nm and of 29.2 nm to 25.1 nm. The protective layer coating 4 in the example of the optical element 1 shown in FIG. 1B, has a single layer of Al₂O₃ having a thickness of 120 nm. In the example shown in FIG. 1D, the protective coating 4, by contrast, has alternating layers 7a and 7b of Al₂O₃ (nₐ=1.84 at 200 nm) and SiO₂ (n_{b}=1.554 at 200 nm), respectively, which have respective thicknesses of about 26.5 nm and of about 32.2 nm. In the example shown in FIG. 1D, the reflective coating 3 or the protective coating 4 is a multilayer coating 3, 4 which is periodic (within the respective subranges), but it will be apparent that it is also possible to use aperiodic multilayer coatings 3, 4 in order to further increase the reflectance R of the optical element 1 if appropriate. F

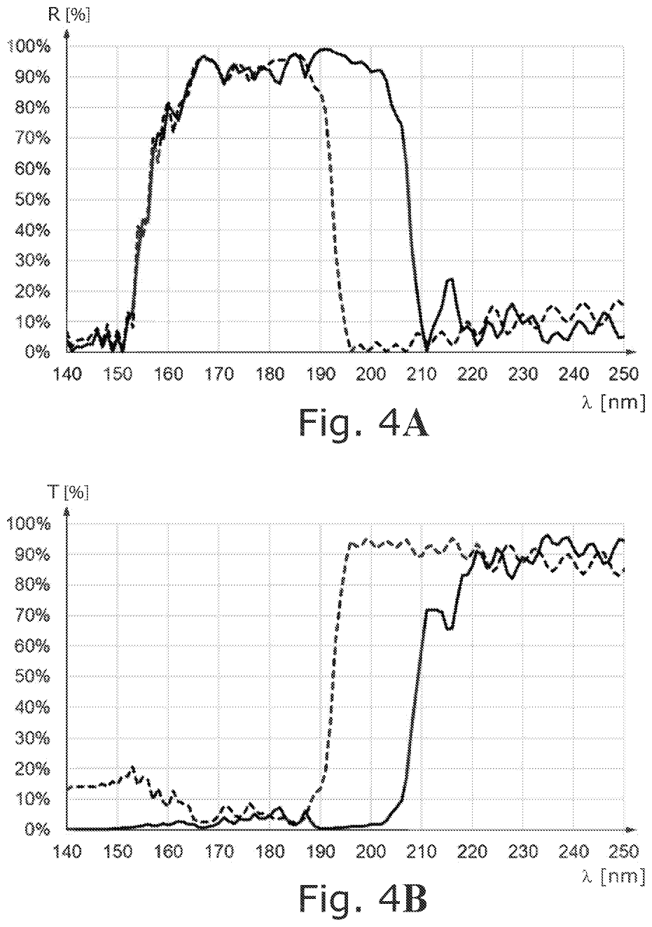

FIG. 4A, shows, as a dotted line, the reflectance R of the optical element 1 of FIG. 1B as a function of the wavelength λ without the complex protective coating 4, i.e., solely with the protective coating 4 with a 120 nm-thick layer of Al₂O₃ as specified on the left-hand side of the table.

FIG. 4A shows, as a solid line, the reflectance R of the optical element 1 of FIG. 1D with the multilayer protective coating 4 as specified on the right-hand side of the table. The example in the left-hand column of the table and of FIG. 4A is designed for the wavelength range of 160 nm to 190 nm. The example in the right-hand column of the table and of FIG. 4B is designed for the wavelength range of 160 nm to 205 nm. Adjustment to the first wavelength range Δλ₁ between 100 nm and 200 nm is possible in the same way with the specified materials.

As apparent from a comparison of the reflectance R of the optical element 1 of FIG. 1B as shown in FIG. 4A and the reflectance of the optical element 1 of FIG. 1D as shown in FIG. 4B, the protective coating 4 shown in FIG. 1D can increase the reflectance R of the optical element 1 within a subrange of the first wavelength range Δλ₁. In order to achieve this, the materials of the protective coating 4 are oxidic materials, for example Al₂O₃, SiO₂, MgO, BeO, HfO₂, Sc₂O₃, Y₂O₃ or Yb₂O₃.

For production of the optical element 1 of FIGS. 1A-D, the reflective coating 3 is first applied with a PVD or CVD process to the rear face 2b of the substrate 2. In a subsequent step, the protective layer coating 4 is applied to the reflective coating 3. If the material of the protective layer coating 4 is an oxidic material, for example aluminium oxide, it may be beneficial when the protective layer coating 4 is applied by an ALD process, since it is possible in this case to achieve a high density of the protective layer coating 4 which enhances the protective effect thereof.

FIG. 2A shows a further method step in which a surface 4a of the protective coating 4 is bonded to a surface 8a of a further layer 8 applied to a further substrate 9 (hereinafter: carrier substrate 9). The material of the further layer 8 is the same material as that of protective layer 4, i.e., Al₂O₃. This facilitates bonding of the two surfaces 4a, 8a to one another by direct bonding, i.e., establishment of a bond that does not need any bonding agent, for example without any adhesive or the like. Direct bonding can be effected, for example, in the way described in the article “Novel hydrophilic SiO₂ wafer bonding using combined surface-activated bonding technique” by Ran He et al., Jpn. J. Appl. Phys. 54, 030218 (2015) which is cited above, and is incorporated herein by reference in its entirety.

FIG. 2B shows the optical element 1 after a process step in which material has been removed from the front face 2a of the substrate 2 in order to reduce the thickness D of the substrate 2. The reduction in thickness D of the substrate 2 to a value of, for example, D=5 mm or D=1 mm or less can reduce the absorption losses due to the passage of the radiation 5 twice through the substrate 2 (i.e., the incident and reflected light each passes through substrate 2) to a negligible value. The material can be removed from the front face 2a of the substrate 2 by lapping and polishing, during which the front face 2a of the substrate 2 is simultaneously converted to a desired shape. It will be apparent that the removal of material of the substrate 2 is not necessary, but merely that the substrate 2 may already have the desired thickness D on bonding to the carrier substrate 9.

In principle, the thickness D of the substrate 2, by virtue of the bonding to the carrier substrate 9, may have a lower thickness D than is the case for an optical element 1 without the carrier substrate 9. The carrier substrate 9 generally has a greater thickness D′ than the substrate 2, which may, for example, be more than about 10 mm.

In the example shown in FIGS. 2A, B, the material of the substrate 2 has a coefficient of thermal expansion α₁ that differs from a coefficient of thermal expansion α₂ of the further substrate 9 by not more than 5*10⁻⁶K⁻¹. In this way, it is possible to reduce deformation of the substrates 2, 9 secured to one another by virtue of different expansion of the substrate materials. This criterion may be fulfilled when the two substrates 2, 9 are manufactured from the same material. However, also possible are combinations of different materials that fulfil this criterion, for example MgF₂ (as substrate 2) and MgO (as further substrate 9).

FIGS. 3A, B show the optical element 1 of FIG. 2B, in which radiation 5 in the first wavelength range Δλ₁ between 100 nm and 200 nm is directed onto the front face 2a of the substrate 2, and in which further radiation 5a in a second wavelength range Δλ₂ between 200 nm and 1000 nm is directed onto the front face 2a of the substrate 2. In the examples shown in FIGS. 3A, B, the reflective coating 3 is transparent to radiation 5 in the second wavelength range Δλ₂.

Such a reflective coating 3 may, for example, be as described above with reference to FIG. 1B or FIG. 1D, meaning that it may take the form of a reflective multilayer coating 3. In this case, the dielectric materials of the reflective multilayer coating 3 may be selected so as to not have too high an absorption for wavelengths in the second wavelength range Δλ₂. FIG. 4B shows the transmittance T of the reflective multilayer coating 3 as a function of the wavelength λ. The dotted line here shows the transmittance T of an optical element 1 having a protective layer 4 with a single layer, in this case 120 nm of Al₂O₃. The optical element 1 thus corresponds to the embodiment shown in FIG. 1B and on the left in the table. The solid line shows the spectral transmittance T of an optical element 1 as shown in FIG. 1D and on the right in the table.

In the examples shown in FIGS. 3A, B, the protective coating 4, the carrier substrate 9 and the coating 8 applied to the carrier substrate 9 are transparent to further radiation 5a within the second wavelength range Δλ₂.

The transparency of the optical element 1 to the further radiation 5a in the second wavelength range Δλ₂ can be utilized advantageously in different ways. In the example shown in FIG. 3A, the optical element 1 serves as a beam divider device that reflects the radiation 5 in the first wavelength range Δλ₁ that hits the front face 2a of the substrate 2 and transmits the further radiation 5a in the second wavelength range Δλ₂ that likewise hits the front face 2a of the substrate 2. The further radiation 5a transmitted by the optical element 1 may, for example, be trapped and absorbed in a beam trap (not shown). The radiation 5 and the further radiation 5a may be generated by one and the same radiation source or, if appropriate, by multiple radiation sources (not shown in FIG. 3A).

In the example shown in FIG. 3B, the radiation 5 in the first wavelength range is directed to the front face 2a of the substrate 2 and reflected at the reflective coating 3. The further radiation 5a in the second wavelength range Δλ₂, in the example shown in FIG. 3B, is generated by a further radiation source 10 which directs the further radiation 5a onto the rear face of the optical element 1, more specifically onto the rear face of the carrier substrate 9b. In particular if the second wavelength range Δλ₂ is at greater wavelengths than the first wavelength range Δλ₁, for example in the Near Infrared (NIR) wavelength range at more than 800 nm, control of the temperature of the substrate 2 can be realized by the further radiation 5a. The further radiation 5a in this case may serve as heating radiation, for example in order to generate a homogeneous temperature distribution in the substrate 2. For this purpose, the further radiation source 10 may be designed to direct the further radiation 5a with an adjustable radiation intensity or radiant power that varies in a location-dependent manner onto the rear face 9b of the carrier substrate 9.

It will be apparent that the optical elements 1 having no carrier substrate 9 that are shown in FIG. 1B or in FIG. 1D can also fulfil the functionality shown in association with FIGS. 3A, B. It is also possible for the geometry of the optical element 1 to differ from the concave geometry shown in FIGS. 1A-D to FIGS. 3A, B. In particular, the substrate 2 may have a planar geometry, i.e., take the form of a planar sheet.

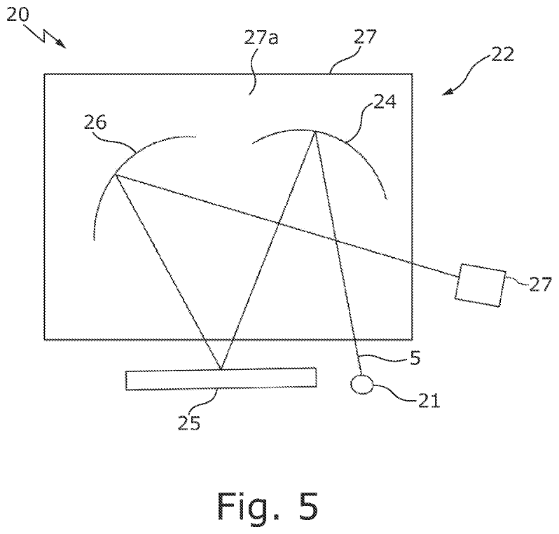

The optical element 1 designed in the manner described above may be used in different optical arrangements. FIG. 5 shows an illustrative design of such an optical arrangement in the form of a wafer inspection system 20. The elucidations that follow are also analogously applicable to inspection systems for inspection of masks.

The wafer inspection device 20 has a radiation source 21, from which the VUV radiation 5 in the first wavelength range Δλ₁ is directed at a wafer 25 by an optical system 22. For this purpose, the radiation 5 is reflected onto the wafer 25 by a concave mirror 24. In the case of a mask inspection device, one possible arrangement would have a mask to be examined in place of the wafer 25.

The radiation reflected, diffracted and/or refracted by the wafer 25 is directed at a detector 27 for further evaluation by a further concave mirror 26, which is likewise associated with the optical system 22. The optical system 22 of the wafer inspection device 20 comprises a housing 27, in the interior 27a of which are disposed the two reflective optical elements or mirrors 24, 26. In the example shown in FIG. 5, a respective mirror 24, 26 is one of the optical elements 1 shown above in association with FIGS. 1A-D or FIGS. 3A, B.

The radiation source 21 may be exactly one radiation source or a combination of multiple individual radiation sources to provide an essentially continuous radiation spectrum. In other examples, it is also possible to use one or more narrowband radiation sources 21. Preferably, the wavelength band of the radiation 15 generated by the radiation source 21 is in the VUV wavelength range Δλ₁ between 100 nm and 200 nm.

It is also possible, though not required, for the radiation source 21 to be designed to generate further radiation 5a in a second wavelength range Δλ₂, which is preferably between 200 nm and 1000 nm. In one such example, the second wavelength range Δλ₂ does not directly adjoin the first wavelength range Δλ₁; instead, there is generally a wavelength range of at least 100 nm between the two wavelength ranges Δλ₁, Δλ₂. In other words, the two wavelength ranges Δλ₁, Δλ₂ are spaced apart on the spectrum.

The optical element 1 described above may also be used advantageously in other optical arrangements, for example in a lithography system, such as a VUV lithography system, or the like.

What is claimed is:

1. An optical element, comprising:
a substrate,
a reflective coating, applied to a rear face of the substrate, for reflecting radiation in a first wavelength range (Δλ₁) between 100 nm and 300 nm, and
a protective coating applied to the reflective coating,
wherein the substrate is formed from a fluoridic material which is transparent to the radiation in the first wavelength range (Δλ₁),
wherein the reflective coating is structured to reflect radiation that passes through the substrate to the reflective coating, and
wherein the protective coating comprises at least one layer of a material non-transparent to the first wavelength range (Δλ₁).

2. The optical element of claim 1, wherein the first wavelength range (Δλ₁) is between 100 nm and 200 nm.

3. The optical element of claim 1, wherein the protective coating has a thickness of at least 50 nm.

4. The optical element of claim 1, wherein the protective coating has at least one layer of an oxidic material which is selected from the group consisting of: Al₂O₃, SiO₂, MgO, BeO, HfO₂, Sc₂O₃, Y₂O₃, Yb₂O₃ and combinations thereof.

5. The optical element of claim 1, wherein the reflective coating consists essentially of aluminium or an aluminium alloy.

6. The optical element of claim 1, wherein the reflective coating comprises a multilayer coating having a plurality of alternating layers composed of materials having different refractive indices (nₐ, n_{b}).

7. The optical element of claim 6, wherein the multilayer coating has at least one layer of a fluoridic material which is selected from the group consisting of: AlF₃, LiF, BaF₂, NaF, MgF₂, CaF₂, LaF₃, GdF₃, HoF₃, YbF₃, YF₃, LuF₃, ErF₃, Na₃AlF₆, Na₅Al₃F₁₄, ZrF₄, HfF₄ and combinations thereof.

8. The optical element of claim 6, wherein at least one layer of aluminium or an aluminium alloy is applied to the multilayer coating.

9. The optical element of claim 6, wherein the protective coating takes the form of a multilayer coating having a plurality of alternating layers of materials having different refractive indices.

10. The optical element of claim 1, further comprising a further substrate on which a surface is formed, which is bonded to a surface of the protective coating by a direct bond, wherein the surface bonded to the surface of the protective coating is formed atop a coating applied to the further substrate.

11. The optical element of claim 10, wherein the substrate has a thickness (D) of less than 5 mm.

12. The optical element of claim 10, wherein the substrate, the further substrate, the protective coating, the reflective coating and the coating of the further substrate are transparent in a second wavelength range (Δλ₂) different than the first wavelength range (Δλ₁), wherein the second wavelength range (Δλ₂) comprises wavelengths greater than wavelengths of the first wavelength range (Δλ₁) and comprises wavelengths between 200 nm and 2000 nm.

13. The optical element of claim 10, wherein a coefficient of thermal expansion (α₁) of the substrate and a coefficient of thermal expansion (α₂) of the further substrate differ by not more than 5*10⁻⁶K⁻¹.

14. The optical element of claim 10, wherein the further substrate is formed from a fluoridic material selected from the group consisting of: CaF₂, MgF₂, LiF, LaF₃, BaF₂ and SrF₂.

15. An optical arrangement of a wafer inspection device, comprising:
a radiation source for generating radiation in a first wavelength range (Δλ₁) between 100 nm and 700 nm; and
an optical element, comprising:
a substrate,
a reflective coating, applied to a rear face of the substrate, for reflecting radiation in a first wavelength range (Δλ₁) between 100 nm and 300 nm, and
a protective coating applied to the reflective coating,
wherein the substrate is formed from a fluoridic material which is transparent to the radiation in the first wavelength range (Δλ₁), and
wherein the reflective coating is structured to reflect radiation that passes through the substrate to the reflective coating;
wherein the optical arrangement is structured to direct the radiation from the radiation source onto a front face of the substrate.

16. The optical arrangement of claim 15, wherein the radiation source or a further radiation source is structured to generate further radiation in a second wavelength range (Δλ₂) different than the first wavelength range (Δλ₁), wherein the second wavelength range (Δλ₂) comprises wavelengths greater than wavelengths of the first wavelength range (Δλ₁) and comprises wavelengths between 200 nm and 2000 nm, and wherein the optical arrangement is structured to direct the further radiation in the second wavelength range (Δλ₂) onto the front face or onto the rear face of the substrate.

17. A method of producing a reflective optical element, comprising:
applying a reflective coating to a rear face of a substrate formed from a fluoridic material, wherein the reflective coating is structured to reflect radiation in a first wavelength range (Δλ₁) between 100 nm and 300 nm, and to transmit further radiation in a second wavelength range (Δλ₂) different than the first wavelength range (Δλ₁), which passes through the substrate to the reflective coating, and wherein the substrate is formed from a material transparent to the radiation in the first wavelength range (Δλ₁) and to the further radiation in the second wavelength range (Δλ₂), and
applying a protective coating to the reflective coating which has a thickness (d) of at least 50 nm.

18. The method of claim 17, further comprising directly bonding a surface of the protective coating to a surface formed on a further substrate.

19. The method of claim 18, wherein the protective coating is formed from an oxidic material, and wherein the surface formed on the further substrate comprises the same material formed on the surface of the protective coating.

20. The method of claim 17, further comprising removing material on a front face of the substrate to reduce a thickness (D) of the substrate.

21. The method of claim 17, wherein the protective coating is applied to the reflective coating by atomic layer deposition.
